(19) United States
(12) Patent Application Publication
(10) Pub. No.: US 2012/0009731 A1
(43) Pub. Date: Jan. 12, 2012

(54) METHOD OF MANUFACTURING PHASE-CHANGE RANDOM ACCESS MEMORY

(76) Inventors: Keun Lee, Ichon-si (KR); Jin Hyock Kim, Ichon-si (KR)

(21) Appl. No.: 13/178,804

(22) Filed: Jul. 8, 2011

(30) Foreign Application Priority Data
Jul. 8, 2010 (KR) 10-2010-0065656

(51) Int. Cl. H01L 21/62

(52) U.S. Cl. 438/102; 257/E21.52

(57) ABSTRACT

A method of a phase-change random access memory (PCRAM) device is provided. The method includes forming a heat pad on a substrate, forming a phase-change material layer by injecting a deposition gas for a phase-change material and a reaction gas on the heat pad, where the phase-change material includes tellurium (Te), forming an upper electrode electrically connected to the phase-change material layer, where the tellurium (Te) is added at a ratio smaller than a normal chemical stoichiometric ratio of materials constituting the phase-change material layer.

### CROSS-REFERENCES TO RELATED APPLICATION

The present application claims priority under 35 U.S.C. 119(a) to Korean application number 10-2010-0065656, filed on Jul. 8, 2010, in the Korean Patent Office, which is incorporated by reference in its entirety as if set forth in full.

### BACKGROUND OF THE INVENTION

1. Technical Field

The inventive concept relates to a semiconductor integrated circuit device and a method of manufacturing the same and, more particularly, to a phase-change random access memory (PCRAM) device including a phase-change material layer and a method of manufacturing the same.

2. Related Art

PCRAM devices perform memory operations by applying Joule heat to a phase-change material through a heat pad serving as a heater. The phase-change material is classified into a crystalline state and an amorphous state according to a heating and cooling method of the phase-change material and the PCRAM devices write and erase data which data state is determined according to an electric resistance between the crystalline state and the amorphous state.

Typically, a chalcogenide (GST)-based material which is comprised of germanium (Ge), antimony (Sb) and tellurium (Te) is used as the phase change material. For example, a phase-change material in which composition of Ge:Sb:Te is 2:2:5 may be used.

With the increase of the semiconductor integration density, a critical dimension (CD) of the phase-change material layer is reduced and thus, an aspect ratio is increased.

Here, when a confined structure is used to improve heating efficiency, the phase-change material layer has to be buried within the contact hole for the confined structure. When the contact hole having a high aspect ratio is formed as discussed above, the phase-change material layer is not uniformly deposited and cause voids such as a seam.

### SUMMARY

According to one aspect of an exemplary embodiment, a method of a phase-change random access memory (PCRAM) device includes preparing forming a heat pad on a semiconductor substrate including a heat pad, forming a phase-change material layer by injecting a deposition gas for a phase-change material containing tellurium (Te) and a reaction gas on the heat pad, wherein the phase-change material includes tellurium (Te), and forming an upper electrode electrically connected to the phase-change material layer. The tellurium (Te) is added at a ratio less smaller than a normal chemical stoichiometric ratio of materials constituting the phase-change material layer.

According to another aspect of an exemplary embodiment, a method of manufacturing a phase-change random access memory (PCRAM) device forming a heat pad on a semiconductor substrate; forming an interlayer insulating layer that defines a contact hole exposing the heat pad, wherein the interlayer insulating layer is formed on a semiconductor substrate; separating ligands of a deposition gas, activating the deposition gas and the ligands of the deposition gas, and simultaneously injecting a reaction gas for adjusting a composition ratio with respect to a chemical stoichiometric ratio of the deposition gas to form a phase-change material layer; and forming an upper electrode electrically connected to the phase-change material layer.

These and other features, aspects, and embodiments are described below in the section entitled “DESCRIPTION OF EXEMPLARY EMBODIMENT”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1 to 4 are cross-sectional views sequentially illustrating a method of a phase-change random access memory (PCRAM) device according to an exemplary embodiment;

FIG. 5 is a flow chart illustrating a method of forming a phase-change material layer of a PCRAM device as a binary material layer; and

FIG. 6 is a flow chart illustrating a method of forming a phase-change material layer of a PCRAM device as a ternary material layer.

### DESCRIPTION OF EXEMPLARY EMBODIMENT

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

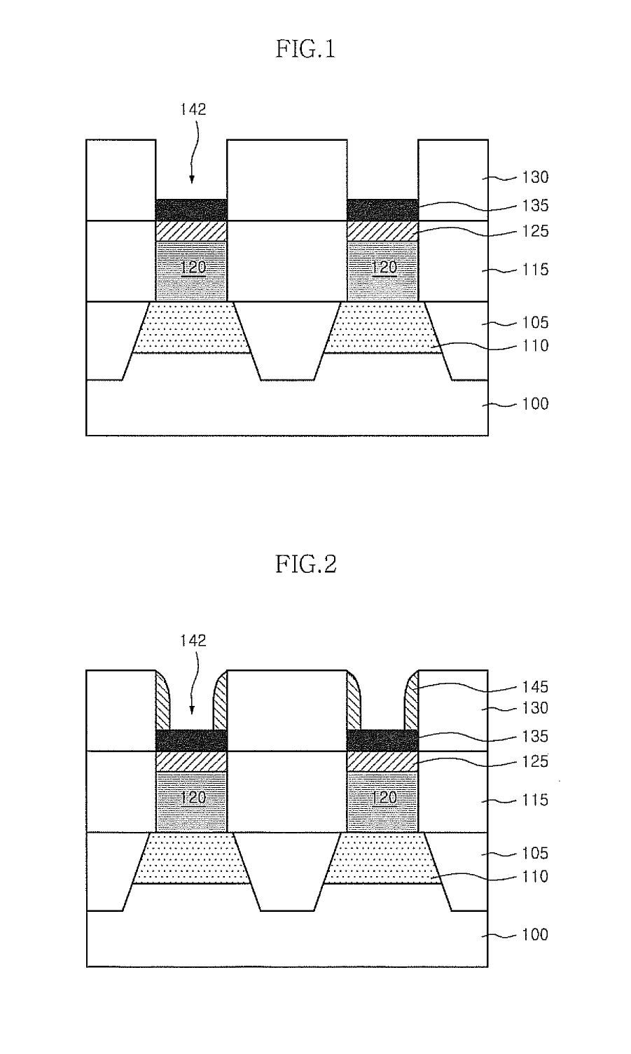

FIGS. 1 to 4 are cross-sectional views sequentially illustrating a method of a phase-change random access memory (PCRAM) device according to an exemplary embodiment.

Referring to FIG. 1, a device isolation layer 105 is formed in a semiconductor substrate 100 by using well known methods for defining active regions. Impurity ions are implanted into the active regions to a desired depth to form junction region type word lines 110 (hereinafter, referred to as junction word lines).

The first interlayer insulating layer 115 is formed on the semiconductor substrate 100 in which the junction word line 100 is formed and the first interlayer insulating layer 115 is etched to expose certain portions of the junction word lines 110, thereby forming diode contact holes (not shown).

At this time, positions at which the diode contact holes are formed may be near interconnections of the junction word lines 110 and bit lines (not shown) to be formed later. A diode 120 as a switching device is formed within each of the contact holes by any reasonably suitable well-known method. In an exemplary embodiment, a PN diode may be used for the diode 120. In some cases, a schottky diode may be used for the diode 120.

According to an example, diode 120 may be formed by forming an n-type selective epitaxial growth (SEG) layer within the diode contact hole and implanting p type impurity ions into an upper portion of the n type SEG layer.

When a metal word line (not shown) is interposed between the diode 120 and the junction word line 110 based on resistance of the junction word line 110, the diode 120 may be constituted of a schottky diode formed of a polysilicon layer.

A transition metal (not shown) is deposited on a resultant structure of the semiconductor substrate 100 in which the diode 120 is formed and a heat treatment process is performed on the resultant structure of the semiconductor substrate 100 to selectively form an ohmic contact layer 125 on the diode 120. Subsequently, the remaining transition metal is removed.

A second interlayer insulating layer 130 is formed on a resultant structure of the semiconductor substrate 100 in which the ohmic contact layer 125 is formed. The second interlayer insulating layer 130 is etched to expose an ohmic contact layer 125, thereby forming a heat electrode contact hole 142.

A conductive material is filled within the heat electrode contact hole 142. For example, the conductive material may be any one of a metal layer such as W, Ti, Mo, Ta or Pt, a metal nitride layer such as TiN, TaN, WN, MoN, NbN, TiSiN, TiAIN, TiBN, ZrSiN, WSiN, WBN, ZrAIN, MoSiN, MoAIN, TaSiN or TaAIN, a silicide layer such as TiSi or TaSi, a metal alloy layer such TiW or a metal oxide (or metal oxy-nitride) layer such as TiON, TiAION, WON, TaON, IrO₂.

Subsequently, the conductive material filled within the heat electrode contact hole 142 is etched back to remain at a bottom of the heat electrode contact hole 142, thereby forming a heat pad 135.

Referring to FIG. 2, a spacer 145 is formed on a sidewall of the heat electrode contact hole 142. The spacer 145 is formed by forming a space insulating layer on an exposed entire surface of the semiconductor surface and performing an etching back process. At this time, the bottom of the spacer 145 is in contact with the upper surface of the heat pad 135. According to an example, the spacer 145 is used for decreasing the size of the heat electrode contact hole 142 and formed of at least any one of a nitride layer and an oxide layer.

Referring to FIG. 3, a phase-change material layer 150 is filled with the heat electrode contact hole 142.

The phase-change material layer 150 is formed on an entire surface of the semiconductor substrate 100 in which the spacer 145 is formed and subsequently etched. At this time, the phase-change material layer 150 is formed to have a thickness for being buried within the heat electrode contact hole 142 by using any one deposition method of chemical vapor deposition (CVD) and atomic layer deposition (ALD). In being etched, the phase-change material layer 150 is etched by a chemical mechanical polishing (CMP) process or a blanket etching process until the second interlayer insulating layer 130 is exposed. At this time, the phase-change material layer 150 contains tellurium (Te) in amount less than a chemical stoichiometric ratio of a compound, where tellurium (Te) is formed on the semiconductor substrate 100 using composition of a reaction gas.

According to an example, for the phase-change material layer 150, a binary material layer such as antimony-tellurium (Sb—Te) or germanium-tellurium (Ge—Te) or a ternary material layer such as germanium-antimony-tellurium (Ge—Sb—Te) may be used. Carbon, nitrogen, oxygen, SiO2 or the like may be additionally doped in the binary material layer or the ternary material layer.

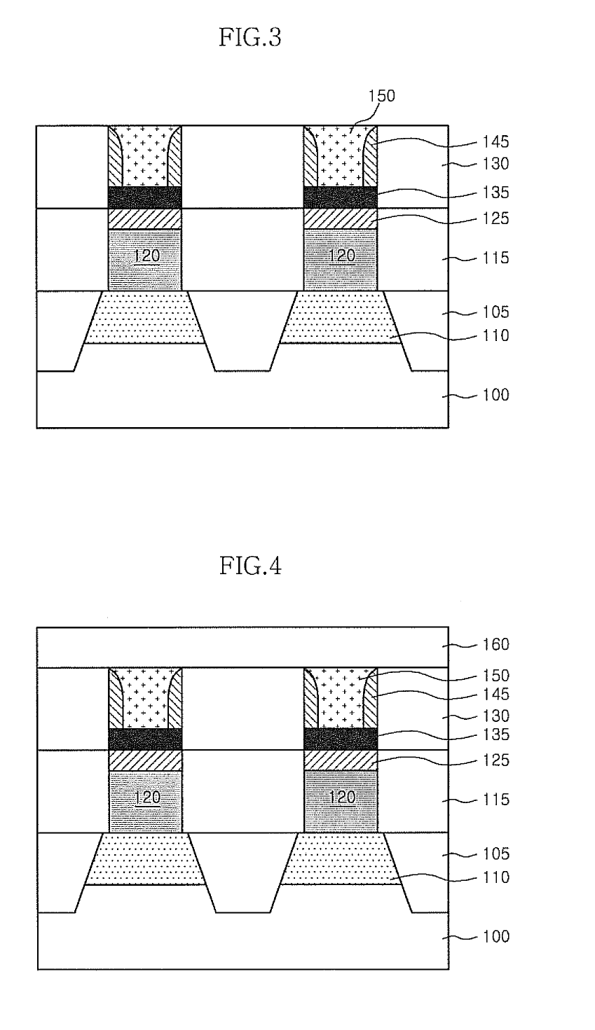

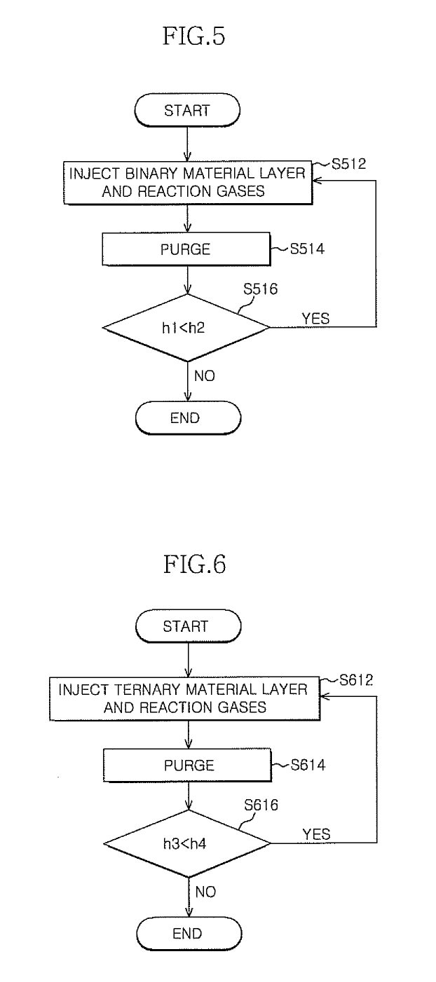

A method of manufacturing a phase-change material layer using the binary material layer or the ternary material layer is described with reference to FIGS. 5 and 6.

First, as one example, FIG. 5 illustrates a method of manufacturing a phase-change material layer using the binary material layer. Antimony-tellurium (Sb—Te) or germanium-tellurium (Ge—Te) used as a deposition gas and a reaction gas are injected on the upper surface of the semiconductor structure in FIG. 2 in which the spacer 145 is formed, where the injection occurs within, for example, a chamber (not shown) by using a CVD or ALD method (S512). Subsequently, a purge process for exhausting remaining gas within the chamber (not shown) is performed (S514). At this time, the purge process step (S514) is performed using well known procedures and thus the detailed description thereof is omitted.

According to an example, the binary material layer may be a mixed gas of antimony-tellurium (Sb—Te) or germanium-tellurium (Ge—Te), and any gas source among Sb and Te may be used as a deposition gas.

When the purge process is completed, a height h1 of deposited binary material layer is compared with a preset threshold height h2 to determine whether or not to perform subsequent processes according to a comparison result (S516). More specifically, when it is determined that the height h1 of the deposited binary material layer is smaller than the threshold height h2, the deposition step (S512) is performed again. When it is determined that the height h1 of the deposited binary material layer is larger than or equal to the threshold height h2, the deposition process is completed.

In injecting the reactive gas together with the main gas (the binary material layer or the ternary material layer) according to an example, ligands of a source (Sb—Te or Ge—Te) used as a raw material are separated, adequate reactivity between atoms is obtained, and reaction of Te is suppressed to allow Sb-rich or Ge-rich environment and thereby maintain the deposited binary material layer to be in amorphous state.

According to an example, well-known ternary material layer such as Sb—Ge—Te may be used. As to the Sb—Ge—Te layer, it may have a composition ratio of 2:2:5 chemically reacts with the spacer 145. However, when the reaction gas is simultaneously injected with the main gas according to an example, appropriate reactivity is obtained so that the phase-change material layer 150 may be uniformly deposited without creating a void or seam by reducing reaction between the deposition material and the spacer. In addition, an aspect ratio of the contact hole may be reduced by the formation of the spacer 145 so that the phase-change material layer can be zo easily buried within the contact hole.

As another example, FIG. 6 illustrates a method of manufacturing a phase-change material layer using the ternary material layer. Germanium-antimony-tellurium (Ge—Sb—Te) functioning as a deposition gas and a reaction gas are injected on the upper surface of the semiconductor structure in FIG. 3 in which the spacer 145 is formed, where the injection occurs within, for example, a chamber (not shown) by using a CVD or ALD method (S612). Subsequently, a purge process for exhausting remaining gas within the chamber (not shown) is performed (S614).

When the purge process is completed, a height h3 of deposited ternary material layer is compared with a preset threshold height h4 and it is determined whether or not to perform subsequent processes according to a comparison result (S616). More specifically, when it is determined that the height h3 of the deposited ternary material layer is smaller than the threshold height h4, the deposition step (S612) is performed again. When it is determined that the height h3 of the deposited ternary material layer is larger than or equal to the threshold height h4, the deposition process is completed.

At this time, the composition ratio of Ge:Sb:Te of the phase-change material layer 150 may be 4:1:5, for example, respectively. Any other reasonably suitable composition ratio that prevents the phase-change material layer 150 from clustering by using a lower growth rate of the phase-change material layer in areas close to the spacer 145 compared to that the same in areas close to the heat pad 135. At this time, the composition ratio may be controlled by adjusting the amount of the reaction gas. As the reaction gas, any one of NH₃ and H₂ may be used.

Referring to FIG. 4, a conduction layer (not shown) is deposited on the resultant structure in which the phase-change material layer 150 is formed and patterned through a conventional process to form an upper electrode 160.

At this time, the upper electrode 160 may be, for example, formed of a titanium (Ti) layer or a titanium nitride (TiN) layer to be electrically connected to the phase-change material layer 150.

According to an exemplary embodiment, a Te-poor material is used as the phase-change material layer to obtain an adequate deposition rate at the sidewall of the heat electrode contact hole. Accordingly, a PCRAM device according to an exemplary embodiment may obtain adequate deposition characteristics and electric characteristics of the phase-change material layer.

While certain embodiments have been described above, it will be understood that the embodiments described are by way of example only. Accordingly, the devices and methods described herein should not be limited based on the described embodiments. Rather, the systems and methods described herein should only be limited in light of the claims that follow when taken in conjunction with the above description and accompanying drawings.

What is claimed is:

1. A method of a phase-change random access memory (PCRAM) device, comprising:
forming a heat pad on a substrate;
forming a phase-change material layer by injecting a deposition gas for a phase-change material and a reaction gas on the heat pad, wherein the phase-change material includes tellurium (Te); and
forming an upper electrode electrically connected to the phase-change material layer,
wherein the tellurium (Te) is added at a ratio smaller than a normal chemical stoichiometric ratio of materials constituting the phase-change material layer.

2. The method of claim 1, wherein the phase-change material layer further includes antimony (Sb).

3. The method of claim 1, wherein the phase-change material layer further includes germanium (Ge).

4. The method of claim 1, wherein the phase-change material layer further includes antimony (Sb) and germanium (Ge).

5. The method of claim 4, wherein a composition ratio of Ge:Sb:Te is 4:1:5, respectively.

6. The method of claim 1, wherein the reaction gas further includes any one of NH₃ and N₂.

7. The method of claim 1, wherein the phase-change material layer is formed by a chemical vapor deposition (CVD) method or an atomic layer deposition (ALD) method.

8. The method of claim 1, wherein the forming of the phase change material layer includes:
simultaneously injecting the tellurium (Te), other source gases and the reaction gas into a chamber to form the phase-change material layer on the semiconductor substrate; and
comparing a height of the phase-change material layer formed on the semiconductor substrate with a threshold height and repeating the simultaneous injection of the tellurium (Te), other source gases and the reaction gas if the height of the phase-change material layer is determined to be smaller than the threshold height.

9. The method of claim 8, further comprising:
performing a planarization process so that the phase-change material layer is planarized to a first height in response to a determination that the height of the phase-change material layer is equal to or greater than the threshold height.

10. The method of claim 9, further comprising purging remaining gases in the chamber after the simultaneous injection of the tellurium (Te), other source gases and the reaction gas.

11. A method of manufacturing a phase-change random access memory (PCRAM) device, comprising:
forming a heat pad on a semiconductor substrate;
forming an interlayer insulating layer that defines a contact hole exposing the heat pad, wherein the interlayer insulating layer is formed on a semiconductor substrate;
separating ligands of a deposition gas, activating the deposition gas and the ligands of the deposition gas, and simultaneously injecting a reaction gas for adjusting a composition ratio with respect to a chemical stoichiometric ratio of the deposition gas to form a phase-change material layer; and
forming an upper electrode electrically connected to the phase-change material layer.

12. The method of claim 11, further comprising forming a switching device connected to the head pad and a word line connected to the switching device before the forming of the heat pad.

13. The method of claim 11, further comprising forming an ohmic contact layer after the forming of the interlayer insulating layer including the contact hole.

14. The method of claim 11, wherein the deposition gas includes a binary material layer.

15. The method of claim 14, wherein the deposition gas includes germanium (Ge) and tellurium (Te) and the ratio of tellurium in the deposition gas is less than a normal chemical stoichiometric ratio of the deposition gas.

16. The method of claim 14, wherein the deposition gas contains antimony (Sb) and tellurium (Te) and the ratio of tellurium in the deposition gas is less than a normal chemical stoichiometric ratio of the deposition gas.

17. The method of claim 11, wherein the deposition gas includes a ternary material layer.

18. The method of claim 17, wherein the deposition gas contains germanium (Ge), tellurium (Te) and the tellurium (Te).

19. The method of claim 18, wherein a composition ratio of Ge:Sb:Te is 4:1:5, respectively.

20. The method of claim 11, wherein the reaction gas further includes any one of NH₃ and H₂.
